(19) United States
(12) Patent Application Publication
(10) Pub. No.: US 2026/0055505 A1
(43) Pub. Date: Feb. 26, 2026

(54) DC BIAS DUAL CROSS FEED MANIFOLD AND A REACTOR USING THE SAME

(71) Applicant: ASM IP Holding B.V., Almere (NL)

(72) Inventors: Vivek Upadhaya, Hwaseong (KR); DaeYoun Kim, Seo-gu (KR); Yonjong Jeon, Yongin-si (KR); JongHa Yu, Suwon-si (KR)

(21) Appl. No.: 19/304,812

(22) Filed: Aug. 20, 2025

Related U.S. Application Data
(60) Provisional application No. 63/686,272, filed on Aug. 23, 2024.

(51) Int. Cl. C23C 16/455; C23C 16/503

(52) U.S. Cl. CPC C23C 16/45544; C23C 16/45536; C23C 16/45565; C23C 16/503

(57) ABSTRACT

A manifold structure used in reactors which process substrates and the reactor equipped with the manifold structure are disclosed. The manifold structure comprises a manifold cylinder disposed vertically and comprising an electrical inlet; a direct current (DC) bias power source configured to supply negatively biased DC to the manifold cylinder and further configured to be connected to the electrical inlet; a top injection unit disposed at topside of the manifold cylinder and comprises a reactant gas inlet tube and configured to receive a reactant gas via the reactant gas inlet tube; and a bottom injection unit disposed at downside of the manifold cylinder and comprises a source gas inlet tube and configured to receive a source gas via the source gas inlet tube, wherein the manifold cylinder is made of a highly electrically conductive material.

### CROSS-REFERENCE TO RELATED APPLICATIONS

This application claims priority to U.S. Provisional Patent Application Ser. No. 63/686,272 filed Aug. 23, 2024 titled DC BIAS DUAL CROSS FEED MANIFOLD AND A REACTOR USING THE SAME, the disclosure of which is hereby incorporated by reference in its entirety.

### FIELD OF INVENTION

The present disclosure relates generally to a substrate processing apparatus, more particularly to an inductively coupled plasma (ICP) atomic layer deposition (ALD) reactor which is equipped with a direct current (DC) biased cross feed manifold.

### BACKGROUND OF THE DISCLOSURE

Conventionally, a reaction chamber employs a manifold for injecting a gas for processing substrates.

But single feed manifold is not efficient in injecting and mixing a gas for substrate processing quality. Moreover, currently an ICP remote plasma unit (RPU) involves feeding reactant gases such as NF3 at the top of the RPU. This means that the NF3 gas may pass the ignition chamber of the RPU.

Feeding NF3 through the RPU can damage the ICP unit with the F radicals made during dissociation of the NF3. Also, directly feeding NF3 into the ignition chamber of the ICP can result in high etch rates, which make it difficult for optimization of processes that need precise control of etch rate, such as deposition etch deposition (DED) process.

And the positive ions contained in the plasma may affect the substrate quality so the positive ions need to be reduced.

Therefore, the present disclosure provides a cross feed manifold which may feed the reactant gas at the bottom of an ICP unit and reduce the positive ions in the plasma flow.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a manifold structure for mixing gases for processing substrates in a reactor, comprising: a manifold cylinder disposed vertically and comprising an electrical inlet; a direct current (DC) bias power source configured to supply negatively biased DC to the manifold cylinder and further configured to be connected to the electrical inlet; a top injection unit disposed at topside of the manifold cylinder and comprises a reactant gas inlet tube and configured to receive a reactant gas via the reactant gas inlet tube; and a bottom injection unit disposed at downside of the manifold cylinder and comprises a source gas inlet tube and configured to receive a source gas via the source gas inlet tube, wherein the manifold cylinder is made of a highly electrically conductive material comprising at least one of Copper (Cu), Aluminum (Al), Zinc (Zn), Nickel (Ni), Iron (Fe), and Lead (Pb) or a mixture thereof, and wherein the top injection unit and the bottom injection unit comprise a ceramic material.

In an aspect, the manifold structure further comprising: a filter disposed in the manifold cylinder.

In an aspect, the filter is disposed a) in the middle of the manifold cylinder, or b) at the topside of the manifold cylinder, or c) at the downside of the manifold cylinder.

In an aspect, the first injection unit further comprises one or more reactant gas inlet tubes.

In an aspect, the second injection unit further comprises one or more source gas inlet tubes.

In an aspect, the manifold structure further comprising a flow control ring disposed inside of the bottom injection unit and the flow control ring comprises a plurality of injection holes for efficient mix of a gas.

In an aspect, the manifold structure further comprising a flow control ring disposed inside of the top injection unit and the flow control ring comprises a plurality of injection holes for efficient mix of a gas.

In accordance with another embodiment there may be provided, a reactor used for processing substrates, comprises: a remote plasma unit (RPU) configured to generate plasma; a manifold disposed between the RPU and a reaction chamber for mixing gases; and a reaction chamber configured to process substrates, wherein the reaction chamber comprises a showerhead, chamber wall and a susceptor for supporting the substrates, and wherein the manifold comprises: a manifold cylinder disposed vertically and comprises an electrical inlet; a top injection unit disposed at topside of the manifold cylinder and comprises a reactant gas inlet tube, and configured to receive a reactant gas via the reactant gas inlet tube; and a bottom injection unit disposed at downside of the manifold cylinder and comprises a source gas inlet tube and configured to receive a source gas via the source gas inlet tube.

In an aspect, the manifold cylinder is made of a highly electrically conductive material comprising at least one of Copper (Cu), Aluminum (Al), Zinc (Zn), Nickel (Ni), Iron (Fe), and Lead (Pb) or a mixture thereof.

In an aspect, the top injection unit and the bottom injection unit comprise ceramic material.

In an aspect, the reactor further comprising: a DC bias power source configured to supply negatively biased DC to the manifold cylinder and further configured to be connected to the electrical inlet.

In an aspect, the manifold further comprises a filter disposed in the manifold cylinder.

In an aspect, the DC bias power source and the manifold cylinder comprise an ion filter which filters out positive ions from a gas mixture in the manifold cylinder.

In an aspect, the filter is disposed a) in the middle of the manifold cylinder, or b) at the topside of the manifold cylinder, or c) at the downside of the manifold cylinder.

In an aspect, the first injection unit further comprises one or more reactant gas inlet tubes.

In an aspect, the second injection unit further comprises one or more source gas inlet tubes.

In an aspect, the reactor further comprising a flow control ring disposed inside of the bottom injection unit and the flow control ring comprises a plurality of injection holes for efficient mix of a gas.

In an aspect, the reactor further comprising a flow control ring disposed inside of the top injection unit and the flow control ring comprises a plurality of injection holes for efficient mix of a gas.

In accordance with another embodiment, there is provided a manifold structure for mixing gases for processing substrates in a reactor, the manifold structure comprising: a top (e.g., cylindrical) manifold section; a bottom (e.g., cylindrical) manifold section, and filter disposed between the top manifold section and the bottom manifold section. The manifold structure can further comprise a direct current (DC) bias power source configured to supply negatively biased DC to the filter.

In an aspect, the top manifold section includes a top injection unit disposed at topside of the top manifold section. The top injection unit comprises a reactant gas inlet tube and is configured to receive a reactant gas via the reactant gas inlet tube.

In an aspect, the bottom manifold section includes a source gas inlet tube and is configured to receive a source gas via the source gas inlet tube.

In an aspect, the top manifold section and/or the bottom manifold section are formed of electrically insulative material, such as a ceramic material described herein.

In an aspect, the filter can be made of a highly electrically conductive material, such as at least one of Copper (Cu), Aluminum (Al), Zinc (Zn), Nickel (Ni), Iron (Fe), and Lead (Pb) or a mixture thereof.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates an overview of a reactor equipped with a manifold structure according to an embodiment of the present disclosure.

FIG. 2 illustrates a close-up view of the manifold structure according to another embodiment of the present disclosure.

FIG. 3 (a) illustrates a filter which may be equipped in the manifold according to another embodiment of the present disclosure; (b) illustrates the positions of a filter in the manifold according to another embodiment of the present disclosure.

FIG. 4 illustrates how the negatively charged manifold cylinder works to reduce positive ions in the manifold cylinder according to an embodiment of the present disclosure.

FIG. 5 (a) illustrates a one-tube injection unit according to an embodiment of the present disclosure; (b) illustrates a two-tube injection unit according to another embodiment of the present disclosure.

FIG. 6 illustrates a view of a manifold structure according to another embodiment of the present disclosure.

FIG. 7 illustrates another view of the manifold structure illustrated in FIG. 6 according to an embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

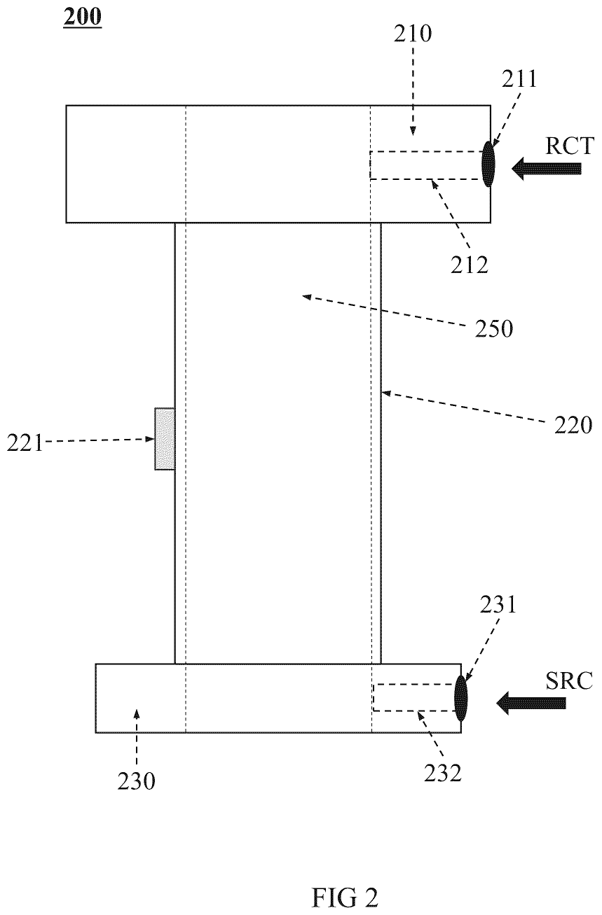

FIG. 2 illustrates a close-up view of a manifold structure 200 according to another embodiment of the present disclosure.

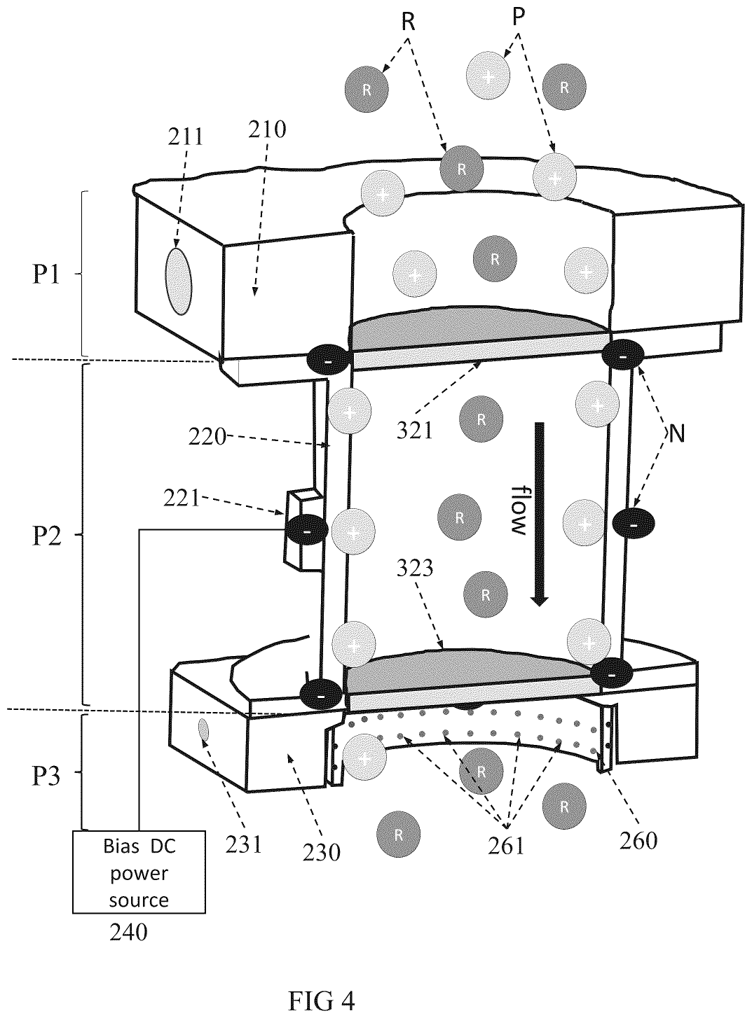

The manifold structure 200 according to the present disclosure comprises a top injection unit 210, a bottom injection unit 230, and a manifold cylinder 220 connecting the top injection unit 210 and the bottom injection unit 230. The manifold structure 200 may have an internal passage 250 for plasma and gas flow. The top injection unit 210 may comprise a reactant gas inlet tube 212 which may inject a reactant gas inserted from a top injection inlet 211. The bottom injection unit 230 may comprise a source gas inlet tube 232 which may inject a source gas inserted from a bottom injection inlet 231. The manifold cylinder 220 may comprise an electrical inlet 221 in its body. The manifold structure 200 may also comprise a bias direct current (DC) power source 240 (illustrated in FIG. 4).

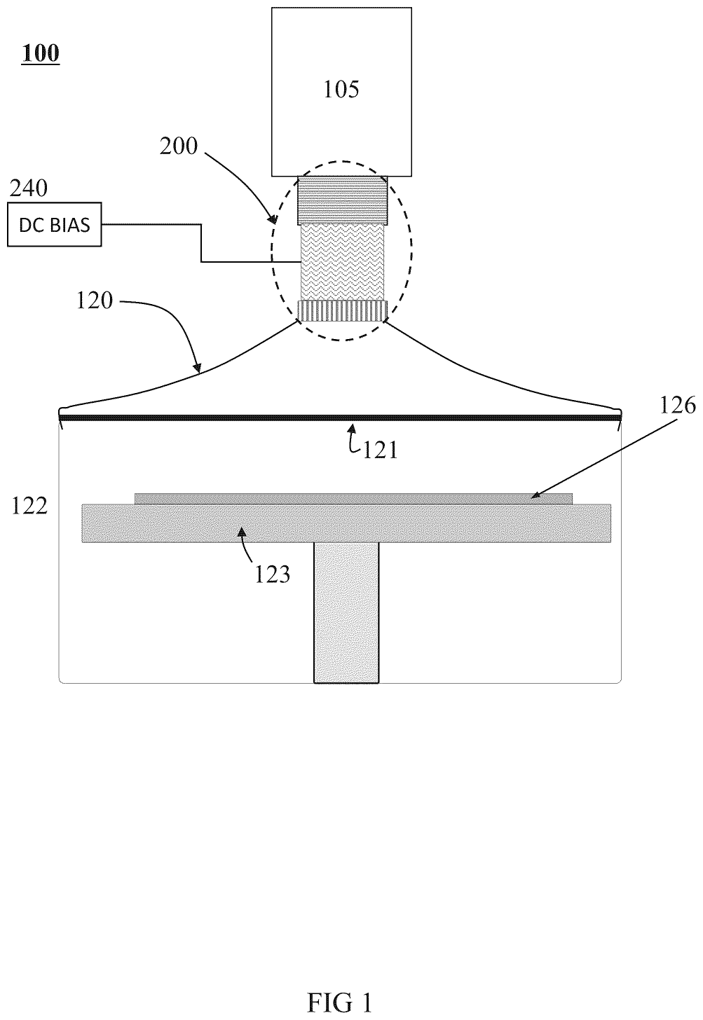

FIG. 1 illustrates an overview of a reactor 100 equipped with a manifold structure 200 according to an embodiment of the present disclosure.

As shown in FIG. 1, the reactor 100 may comprise a remote plasma unit (RPU) 105, a manifold structure 200 connected to a bias direct current (DC) power source 240, reaction chamber 120, a showerhead 121, a chamber wall 122, and a susceptor 123. A substrate 126 may be placed on the susceptor 123.

Plasma species from a plasma generated in the RPU 105 may come down through the manifold structure 200. The plasma species may comprise radicals R and positive ions P as shown in FIG. 4. FIG. 4 illustrates how the negatively charged manifold cylinder works to reduce positive ions in the manifold cylinder according to an embodiment of the present disclosure. The radicals (R) are electrically neutral while the positive ions (P) are electrically positive.

The manifold cylinder 220 may be charged with negatively biased DC supplied from the bias DC power source 240 connected via an electrical inlet 221. For efficient negative charging, the manifold cylinder 220 may be made of a highly electrically conductive material comprising at least one of Copper (Cu), Aluminum (Al), Zinc (Zn), Nickel (Ni), Iron (Fe), and Lead (Pb) or a mixture of them while the top injection unit 210 and the bottom injection unit 230 may be made of ceramic material for electrical insulation to the RPU 105 (top injection unit 210) and to the reaction chamber 120 (bottom injection unit 230).

In phase 1 (P1), the radicals (R) and positive ions (P) may be formed in the plasma generated in the RPU 105. The plasma species would be mixed with a reactant gas injected from the top injection inlet 211.

In phase 2 (P2), the bias DC power source 240 may negatively charge the manifold cylinder 220. Therefore, the manifold cylinder 220 may be charged negatively (N). While the plasma species, i.e., the radicals (R) and positive ions (P), flows downward toward the reaction chamber 120, the electrically neutral radicals (R) may flow downward without any outside effect. But the positive ions (P) may be affected by the electrical force therefore the positive ions (P) may be directed toward the negatively charged manifold cylinder 220 and somewhat eliminated from the plasma mixture.

In phase 3 (P3), when a source gas may be injected from the bottom injection inlet 231 in the bottom injection unit 230, the density of radicals (R) may be much higher than that of positive ions (P). For better mixture, a flow control ring 260 with a plurality of injection holes 261 may be placed inside of the bottom injection unit 230. Though not illustrated in the drawings, a flow control ring with a plurality of injection holes may also be placed inside of the top injection unit 210.

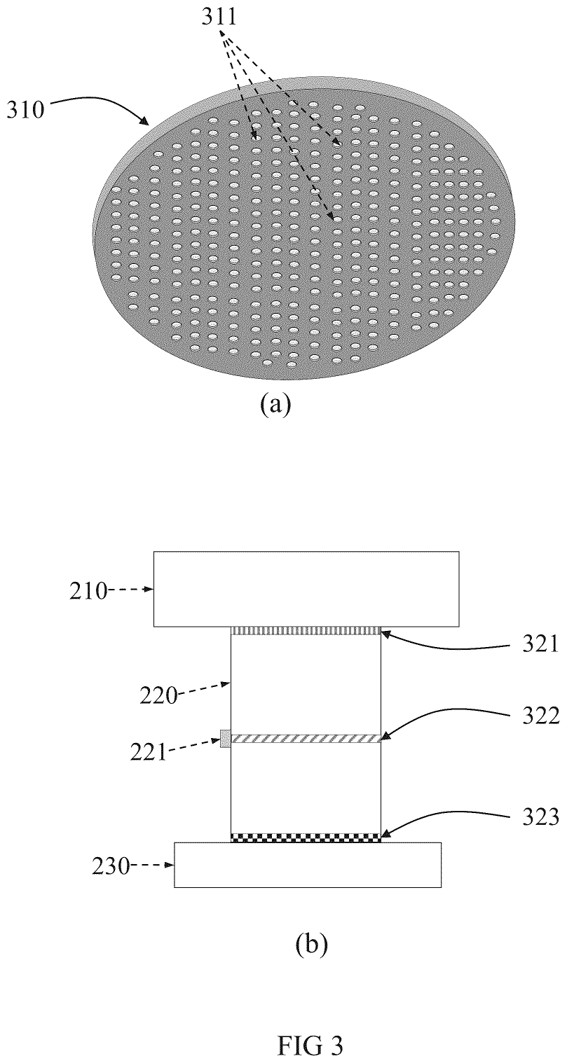

For better positive ion elimination, a filter may be placed inside of the manifold cylinder 220. FIGS. 3 (a) & (b) illustrate a filter 310 which may be equipped in the manifold cylinder 220 (FIG. 3 (a)) and the positions of the filter 310 in the manifold cylinder 220 (FIG. 3(b)) respectively. The filter 310 may be made of the same material of the manifold cylinder 220 for attracting the positive ions (P). The filter 310 may be circle shaped to fit into the manifold cylinder 220 and may comprise a plurality of holes 311.

The filter 310 may be placed in various places in the manifold cylinder 220. For example, the filter 310 may be placed in the middle of the manifold cylinder (322), at the mouth of the top injection unit 210, i.e., at the topside of the manifold cylinder (321), or at the mouth of the bottom injection unit 230, i.e., at the downside of the manifold cylinder (323). In some cases, more than one filter may be placed on various positions in the manifold cylinder 220.

The top injection unit 210 and the bottom injection unit 230 may have more than one injection tube.

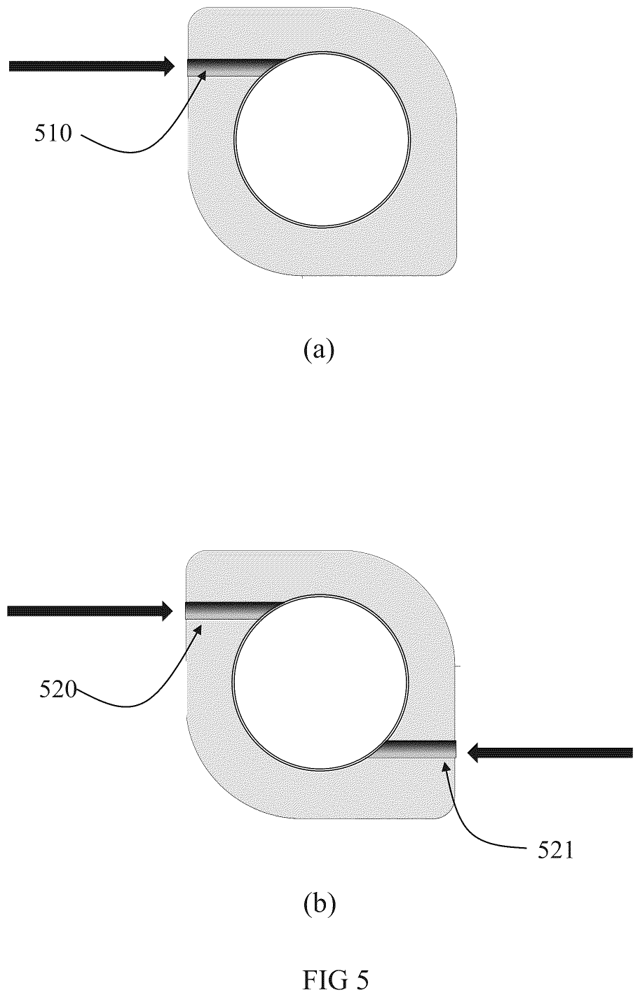

FIGS. 5 (a) and (b) illustrates examples of one-tubed & two-tubed (top and bottom) injection unit according to the present disclosure.

The top injection unit 210 may comprise a reactant gas inlet tube 510 in some cases but the top injection unit 210 may comprise reactant gas inlet tubes 520, 521 in some other cases. The bottom injection unit 230 may comprise a source gas inlet tube 510 in some cases but the bottom injection unit 230 may comprise source gas inlet tubes 520, 521 in some other cases just like the top injection unit 210. The number of inlet tubes of the top injection unit 210 and the bottom injection unit 230 may vary in different circumstances.

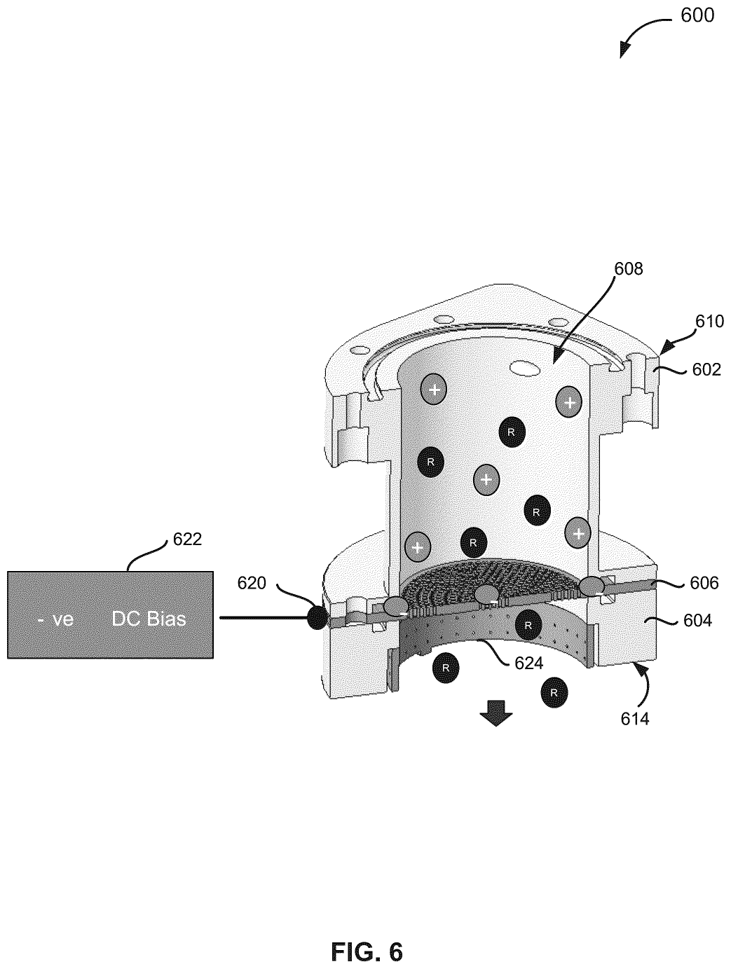

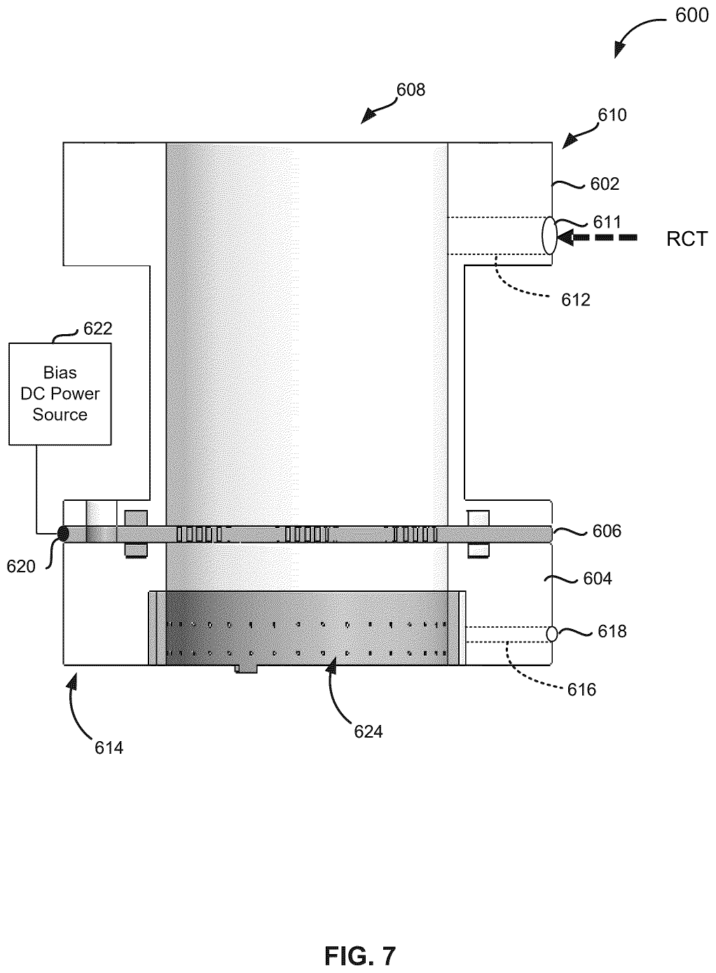

FIGS. 6 and 7 illustrate another manifold structure 600 according to the present disclosure. Manifold structure 600 can be used in connection with reactor system 100 described above.

In the illustrated example, manifold structure 600 includes a top (e.g., cylindrical) manifold section 602, a bottom (e.g., cylindrical) manifold section 604, and filter 606 disposed (e.g., directly) between top manifold section 602 and the bottom manifold section 604. As above, manifold structure 600 may have an internal passage 608 for plasma species and/or gas flow. Manifold structure 600 can also include a flow control ring 624, which can be the same or similar to flow control ring 260, described above, in top manifold section 602 and/or bottom manifold section 604.

Top manifold section 602 can include a top injection unit 610. Top injection unit 610 may comprise a reactant gas inlet tube 612 which may inject a reactant gas inserted from a top injection inlet 611. Top manifold section 602 can be formed of electrically insulative material, such as insulating ceramic material(s). By way of examples, top manifold section 602 can be formed of one or more of alumina, aluminum nitride, and/or quartz (SiO₂).

Bottom manifold section 604 includes a bottom injection unit 614. Bottom injection unit 614 may comprise a source gas inlet tube 616 which may inject a source gas inserted from a bottom injection inlet 618. Bottom manifold section 604 can be formed of any of the materials noted above in connection with top manifold section 602.

Top injection unit 610 and/or bottom manifold section 604 can each include one or more injection tubes. Example configurations are described above in connection with FIG. 5.

Filter 606 can be as described above in connection with FIG. 3. Filter 606 may be formed of highly electrically conductive material, such as the highly electrically conductive material described herein. Filter 606 can also comprise an electrical inlet 620, which can be the same or similar to electrical inlet 221.

Manifold structure 600 may also comprise a bias direct current (DC) power source 622 to apply a -ve DC bias on filter 606. Applying DC bias on the sandwiched filter to trap charged ions can reduce ion damage on film and allow for radical dominant reactions, which are often desired.

The above-described arrangements of apparatus are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A manifold structure for mixing gases for processing substrates in a reactor, comprising:
a manifold cylinder disposed vertically and comprising an electrical inlet;
a direct current (DC) bias power source configured to supply negatively biased DC to the manifold cylinder and further configured to be connected to the electrical inlet;
a top injection unit disposed at topside of the manifold cylinder and comprises a reactant gas inlet tube and configured to receive a reactant gas via the reactant gas inlet tube; and
a bottom injection unit disposed at downside of the manifold cylinder and comprises a source gas inlet tube and configured to receive a source gas via the source gas inlet tube, wherein the manifold cylinder is made of a highly electrically conductive material comprising at least one of Copper (Cu), Aluminum (Al), Zinc (Zn), Nickel (Ni), Iron (Fe), and Lead (Pb) or a mixture thereof, and wherein the top injection unit and the bottom injection unit comprise a ceramic material.

2. The manifold structure according to claim 1, further comprising:
a filter disposed in the manifold cylinder.

3. The manifold structure according to claim 2, wherein the filter is disposed a) in the middle of the manifold cylinder, or b) at the topside of the manifold cylinder, or c) at the downside of the manifold cylinder.

4. The manifold structure according to claim 1, wherein the first injection unit further comprises one or more reactant gas inlet tubes.

5. The manifold structure according to claim 1, wherein the second injection unit further comprises one or more source gas inlet tubes.

6. The manifold structure according to claim 1, further comprising:
a flow control ring disposed inside of the bottom injection unit and the flow control ring comprises a plurality of injection holes for efficient mix of a gas.

7. The manifold structure according to claim 1, further comprising:
a flow control ring disposed inside of the top injection unit and the flow control ring comprises a plurality of injection holes for efficient mix of a gas.

8. A reactor used for processing substrates comprises:
a remote plasma unit (RPU) configured to generate plasma;
a manifold disposed between the RPU and a reaction chamber for mixing gases; and
a reaction chamber configured to process substrates, wherein the reaction chamber comprises a showerhead, chamber wall and a susceptor for supporting the substrates, and wherein the manifold comprises:
a manifold cylinder disposed vertically and comprises an electrical inlet;
a top injection unit disposed at topside of the manifold cylinder and comprises a reactant gas inlet tube, and configured to receive a reactant gas via the reactant gas inlet tube; and
a bottom injection unit disposed at downside of the manifold cylinder and comprises a source gas inlet tube and configured to receive a source gas via the source gas inlet tube.

9. The reactor according to claim 8, wherein the manifold cylinder is made of a highly electrically conductive material comprising at least one of Copper (Cu), Aluminum (Al), Zinc (Zn), Nickel (Ni), Iron (Fe), and Lead (Pb) or a mixture thereof.

10. The reactor according to claim 8, wherein the top injection unit and the bottom injection unit comprise ceramic material.

11. The reactor according to claim 8, further comprising:
a DC bias power source configured to supply negatively biased DC to the manifold cylinder and further configured to be connected to the electrical inlet.

12. The reactor according to claim 8, wherein the manifold further comprises a filter disposed in the manifold cylinder.

13. The reactor according to claim 11, wherein the DC bias power source and the manifold cylinder comprise an ion filter which filters out positive ions from a gas mixture in the manifold cylinder.

14. The reactor according to claim 12, wherein the filter is disposed a) in the middle of the manifold cylinder, or b) at the topside of the manifold cylinder, or c) at the downside of the manifold cylinder.

15. The reactor according to claim 8, wherein the first injection unit further comprises one or more reactant gas inlet tubes.

16. The reactor according to claim 8, wherein the second injection unit further comprises one or more source gas inlet tubes.

17. The reactor according to claim 8, further comprising:
a flow control ring disposed inside of the bottom injection unit and the flow control ring comprises a plurality of injection holes for efficient mix of a gas.

18. The reactor according to claim 8, further comprising:
a flow control ring disposed inside of the top injection unit and the flow control ring comprises a plurality of injection holes for efficient mix of a gas.

19. A manifold structure for mixing gases for processing substrates in a reactor, the manifold structure comprising:
a top manifold section;
a bottom manifold section;
a filter disposed between the top manifold section and the bottom manifold section; and
a direct current (DC) bias power source configured to supply negatively biased DC to the filter.

20. The manifold structure of claim 19, further comprising a flow control ring disposed inside of a bottom injection unit of the bottom manifold section.
